(19) United States
(12) Patent Application Publication
(10) Pub. No.: US 2018/0006230 A1
(43) Pub. Date: Jan. 4, 2018

(54) PHYSICAL UNCLONABLE FUNCTION (PUF) INCLUDING A PLURALITY OF NANOTUBES, AND METHOD OF FORMING THE PUF

(71) Applicant: International Business Machines Corporation, Armonk, NY (US)

(72) Inventors: Qing CAO, Yorktown Heights, NY (US); Kangguo CHENG, Schenectady, NY (US); Zhengwen LI, Chicago, IL (US); Fei LIU, Yorktown Heights, NY (US)

(21) Appl. No.: 15/197,224

(22) Filed: Jun. 29, 2016

(51) Int. Cl. H01L 51/00; G06K 19/07; H01L 23/00; G01N 27/04

(52) U.S. Cl. CPC H01L 51/0048; H01L 51/0021; H01L 51/0012; G01N 27/041; G06K 19/0718; H01L 23/573

(57) ABSTRACT

A physical unclonable function (PUF) includes a first plurality of carbon nanotubes (CNTs) formed in a first direction, a second plurality of CNTs formed on the first plurality of CNTs in a second direction which is substantially perpendicular to the first direction, and a plurality of contacts connected at an end portion of the first plurality of CNTs and the second plurality of CNTs.

### BACKGROUND OF THE INVENTION

### Field of the Invention

The present invention relates to a physical unclonable function (PUF), and more particularly, to a PUF which includes a plurality of carbon nanotubes.

### Description of the Related Art

Chip authentication is becoming more and more critical for cloud and mobile applications. The ideal chip authentication should be hard to attack, randomly generated, and low cost.

Conventionally, chip authentication is commonly performed by using a physical unclonable function (PUF). A PUF is a challenge-response mechanism in which the mapping between a challenge and the corresponding response is dependent on the complex and variable nature of a physical material.

FIG. 1 illustrates a conventional PUF 100. As illustrated in FIG. 1, the PUF 100 is an integrated circuit (IC) which is formed on a semiconductor chip 110, and uses a chip-unique challenge-response mechanism exploiting manufacturing process variation inside the integrated circuit (IC). The relation between the challenge and the corresponding response is determined by complex, statistical variation in logic and interconnect in an IC, and therefore, may be used as a unique identifier (e.g., similar to a fingerprint, DNA, bar code, etc.) which is associated with the semiconductor chip 110 on which the PUF 100 is formed.

That is, the conventional PUF 100 is basically a variability-aware circuit which is able to detect the mismatch in circuit components caused by manufacturing process variation. If the PUF 100 (e.g., variability aware circuit) is instantiated on several different semiconductor chips, then each of the PUF instantiations will produce unique responses when supplied with the same challenge C.

### SUMMARY

In view of the foregoing and other problems, disadvantages, and drawbacks of the aforementioned conventional devices and methods, an exemplary aspect of the present invention is directed to a PUF including a plurality of carbon nanotubes and a method of forming the PUF.

An exemplary aspect of the present invention is directed to a physical unclonable function (PUF) includes a first plurality of carbon nanotubes (CNTs) formed in a first direction, a second plurality of CNTs formed on the first plurality of CNTs in a second direction which is substantially perpendicular to the first direction, and a plurality of contacts connected at an end portion of the first plurality of CNTs and the second plurality of CNTs.

Another exemplary aspect of the present invention is directed to a method of forming a physical unclonable function (PUF), the method including forming a first plurality of carbon nanotubes (CNTs) formed in a first direction, forming a second plurality of CNTs formed on the first plurality of CNTs in a second direction which is substantially perpendicular to the first direction, and forming a plurality of contacts connected at an end portion of the first plurality of CNTs and the second plurality of CNTs.

Another exemplary aspect of the present invention is directed to a device for reading a physical unclonable function (PUF) which is affixed to an object and includes a plurality of crossed carbon nanotubes (CNTs), including a current source for applying a current to a plurality of contacts, and a resistance detector for detecting a junction resistance for the plurality of crossed CNTs.

With its unique and novel features, the present invention provides a PUF which is significantly smaller than a conventional PUF and is inexpensive and easy to manufacture.

### BRIEF DESCRIPTION OF THE DRAWINGS

The foregoing and other objects, aspects and advantages will be better understood from the following detailed description of the embodiments of the invention with reference to the drawings, in which:

FIG. 1 illustrates a conventional PUF 100;

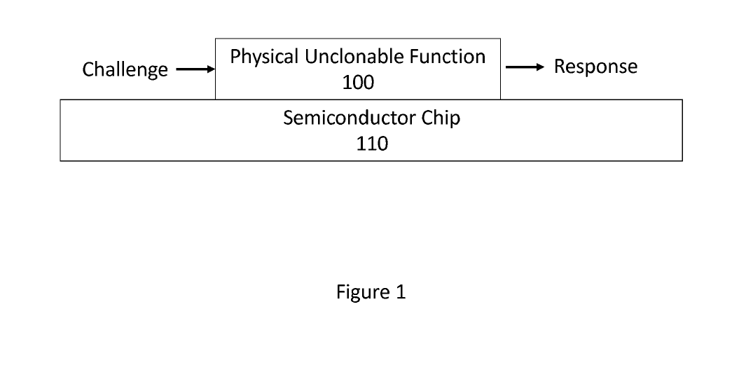

FIG. 2A illustrates a topdown (i.e., plan view) of a physical unclonable function (PUF) 200, according to an exemplary aspects of the present invention, and FIG. 2B illustrates a cross-sectional view of the PUF 200 along A-A in FIG. 2A, according to an exemplary aspects of the present invention;

FIG. 3 illustrates a method 300 of forming a physical unclonable function (PUF), according to an exemplary aspect of the present invention;

FIG. 4A illustrates a topdown view (e.g., plan view) in the forming of a first alignment layer 450, according to an exemplary aspect of the present invention, and FIG. 4B illustrates a cross sectional view along line A-A in FIG. 4A in the forming of the first alignment layer 450, according to an exemplary aspect of the present invention;

FIG. 5A illustrates a topdown view (e.g., plan view) in the forming of a second alignment layer 460, according to an exemplary aspect of the present invention, and FIG. 5B illustrates a cross sectional view along line A-A in FIG. 5A in the forming of the second alignment layer 460, according to an exemplary aspect of the present invention;

FIG. 6A illustrates a topdown view (e.g., plan view) in the forming of a plurality of alignment columns 460a, according to an exemplary aspect of the present invention, and FIG. 6B illustrates a cross sectional view along line A-A in FIG. 6A in the forming of the alignment columns 460a, according to an exemplary aspect of the present invention;

FIG. 7A illustrates a topdown view (e.g., plan view) in the depositing of a first plurality of CNTs 410, according to an exemplary aspect of the present invention, and FIG. 7B illustrates a cross sectional view along line A-A in FIG. 7A in the depositing of a first plurality of CNTs 410, according to an exemplary aspect of the present invention;

FIG. 8A illustrates a topdown view (e.g., plan view) in the forming of a third alignment film 470 and a fourth alignment film 480, according to an exemplary aspect of the present invention, and FIG. 8B illustrates a cross sectional view along line A-A in FIG. 8A in the forming of the third alignment film 470 and the fourth alignment film 480, according to an exemplary aspect of the present invention;

FIG. 9A illustrates a topdown view (e.g., plan view) in the forming of a plurality of alignment columns 480a, according to an exemplary aspect of the present invention, and FIG. 9B illustrates a cross sectional view along line A-A in FIG. 9A in the forming of the alignment columns 480a, according to an exemplary aspect of the present invention;

FIG. 10A illustrates a topdown view (e.g., plan view) in the depositing of the second plurality of CNTs 420, according to an exemplary aspect of the present invention, and FIG. 9B illustrates a cross sectional view along line A-A in FIG. 10A in the depositing of the second plurality of CNTs 420, according to an exemplary aspect of the present invention;

FIG. 11A illustrates a topdown view (e.g., plan view) in the forming of a protective film 490, according to an exemplary aspect of the present invention, and FIG. 11B illustrates a cross sectional view along line A-A in FIG. 11A in the forming of the protective film, according to an exemplary aspect of the present invention;

FIG. 12A illustrates a topdown view (e.g., plan view) in the forming of the contacts 430a, 430b, according to an exemplary aspect of the present invention, and FIG. 12B illustrates a cross sectional view along line A-A in FIG. 12A in the forming of the contacts 403a, 430b, according to an exemplary aspect of the present invention;

FIG. 13A illustrates a topdown view (e.g., plan view) in the formation of the junction between two layers of nanotubes by etching away the alignment films and the protective film in the trench T, according to an exemplary aspect of the present invention, and FIG. 13B illustrates a cross sectional view along line A-A in FIG. 13A in the forming of the trench T, according to an exemplary aspect of the present invention;

FIG. 14A illustrates a device 1400 for reading a physical unclonable function (PUF) which is affixed to an object such as the semiconductor chip 1401 and includes a plurality of crossed carbon nanotubes (CNTs), according to an exemplary aspect of the present invention; and

FIG. 14B illustrates the device 1400, according to another exemplary aspect of the present invention.

### DETAILED DESCRIPTION OF THE EXEMPLARY EMBODIMENTS OF THE INVENTION

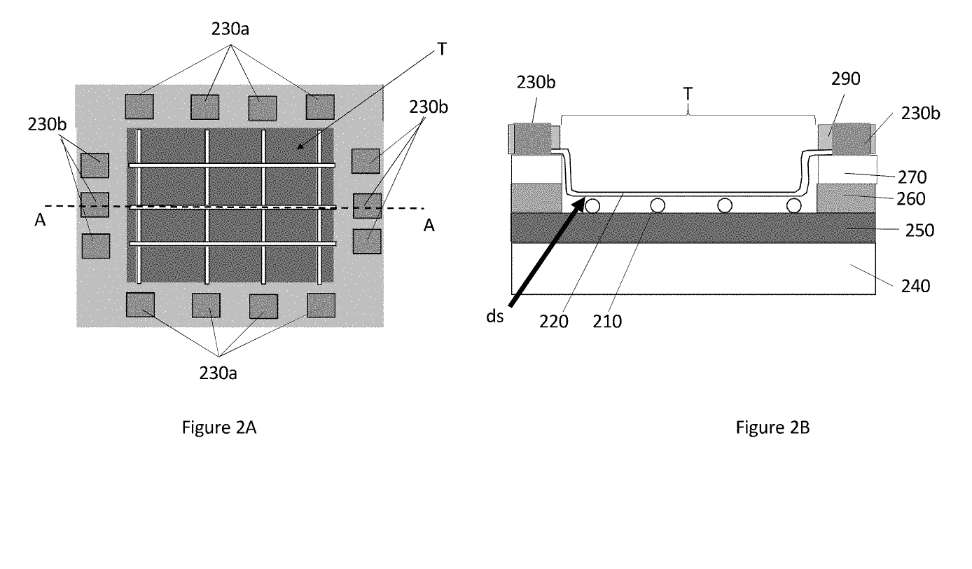

Referring now to the drawings, FIGS. 2A-14B illustrate the exemplary aspects of the present invention.

A problem with the conventional PUF 100 is that it is relatively large. Thus, in implementing a conventional PUF 100 on the semiconductor chip 110, the conventional PUF 100 occupies a large portion of the semiconductor chip 110.

An exemplary aspect of the present invention, on the other hand, provides a PUF which is significantly smaller than a conventional PUF and is inexpensive and easy to manufacture. That is, unlike conventional PUFs which are relatively large (e.g., relative to the size of a semiconductor chip), an exemplary aspect of the present invention may provide an ultrahigh integration density.

In particular, a PUF (e.g., crossbar aligned carbon nanotube (CNT) PUF) according to an exemplary aspect of the present invention may utilize a junction resistance between two crossed carbon nanotubes (CNTs). The junction resistance demonstrates a wide random variation, as a small difference in the separation distance at the junction point leads to a large change in the tunneling barrier.

Further, the PUF may provide a possibility for achieving ultimate density. For example, at a tube pitch of 8 nm, each junction only occupies 64 nm².

Referring again to the drawings, FIG. 2A illustrates a topdown (i.e., plan view) of a physical unclonable function (PUF) 200, according to an exemplary aspects of the present invention, and FIG. 2B illustrates a cross-sectional view of the PUF 200 along A-A in FIG. 2A, according to an exemplary aspects of the present invention.

As illustrated in FIG. 2A, the PUF 200 includes a first plurality of carbon nanotubes (CNTs) 210 (also referred to herein as “first CNTs”) formed in a first direction (e.g., into and out of the page), and a second plurality of CNTs 220 (also referred to herein as “second CNTs”) formed on the first plurality of CNTs 210 in a second direction which is substantially perpendicular to the first direction.

The PUF 200 further includes a plurality of contacts 230a-230b connected at an end portion of the first plurality of CNTs 210 and the second plurality of CNTs 220. In particular, the plurality of contacts 230a are connected to end portions of the first plurality of CNTs 210, and the plurality of contacts 230b are connected to end portions of the second plurality of CNTs 220. The plurality of contacts 230a-230b may be formed of a conductive material such as metal (e.g., gold), polysilicon, etc. Further, the spacing between the centers of the contacts 230a may be substantially the same as the pitch between the first plurality of CNTs 210, and the spacing between the centers of the contacts 230b may be substantially the same as the pitch between the second plurality of CNTs 220.

The first plurality of CNTs 210 and the second plurality of CNTs 220 may include, for example, single-walled nanotubes (SWNT) including a diameter in a range of 0.6 nm to 3 nm. The diameter of the first plurality of CNTs 210 may be different from the diameter of the second plurality of CNTs 220. In addition, the first plurality of CNTs 210 may have diameters which are different from one another, and the second plurality of CNTs 220 may have diameters which are different from one another.

Further, a length of the first plurality of CNTs 210 and the second plurality of CNTs 220 may be in a range from 30 nm to a few microns. It should be noted that the length of the second plurality of CNTs 220 may be greater (e.g., about 5 nm to 10 nm greater) than the length of the first plurality of CNTs 210, due to the additional length of the second plurality of CNTs 220 between the contacts 230b and the first plurality of CNTs 210.

Further, although FIGS. 2A-2B illustrate the PUF 200 including four (4) first CNTs 210 and three (3) second CNTs 220, this is in no way limiting the PUF 200. That is, PUF 200 may include two or more first CNTs 210 and two or more second CNTs 220.

However, in order to minimize the size of the PUF, the number of first CNTs 210 and second CNTs 220 should be the minimum necessary to provide a desired level of security. That is, although it may be the case that the more CNTs used in the PUF, the greater the level of security that can be provided by the PUF, the security interest must be balanced with the interest in size minimization (i.e., using the smallest number of CNTs possible) and cost (i.e., the more CNTs used in the PUF, the more expensive it is to manufacture the PUF). Further, the number of first CNTs 210 may be the same or different than the number of second CNTs 220.

A pitch between the first plurality of CNTs 210, and a pitch between the second plurality of CNTs may be in a range from 5 nm to 200 nm. However, the pitch should be kept to a minimum in order to minimize the size of the PUF 200. Further, the pitch between the first plurality of CNTs 210 may be the same as or different than the pitch between the second plurality of CNTs 220.

The first plurality of CNTs 210 may be substantially aligned (e.g., parallel) in the first direction, and the second plurality of CNTs may be substantially aligned (e.g., parallel) in the second direction.

Further, the first plurality of CNTs 210 may be formed in a first horizontal plane and the second plurality of CNTs 220 may be formed in a second horizontal plane which is substantially parallel to the first plane. However, it is not necessary that the first plurality of CNTs 210 are formed at the same height (e.g., distance from a surface of a substrate on which the PUF 200 is formed) Likewise, it is not necessary that the second plurality of CNTs 220 are formed at the same height.

In particular, at the junction between a first CNT 210 and a second CNT 220 (i.e., a location at which the second CNT 220 crosses over the first CNT 210), a separation distance dₛ in a vertical direction (e.g., a direction substantially perpendicular to the surface of the substrate on which the PUF 200 is formed) between the first CNT 210 and the second CNT 220 may be in a range from 3.34 \acute{Å} (e.g., Van der Waals distance) to 40 \acute{Å}.

It is important to note that the separation distance dₛ may vary from one junction to the next. This feature may increase the randomness in the PUF 200, since a small difference in the separation distance dₛ at the junction leads to a large change in the tunneling barrier. Therefore, a wide random variation in the junction resistance may be provided by a slight variation in separation distance dₛ among the first CNTs 210 and the second CNTs 220.

Referring again to FIGS. 2A and 2B, the PUF 200 may include a substrate 240 and a first alignment layer 250 formed on the substrate 240, the first plurality of CNTs 210 being formed on the first alignment layer 250. The PUF 200 may also include a second alignment layer 260 formed on the first alignment layer 250, a third alignment layer 270 formed on the second alignment layer 260, a fourth alignment layer 280 formed on the third alignment layer 270, and a protective film 290 formed on the fourth alignment layer 280.

A trench T may be formed in the protective film 290 and in the second, third, and fourth alignment films 260, 270, 280, a surface of the first alignment film 250 forming a bottom of the trench T. The second plurality of CNTs 220 may cross over the first plurality of CNTs 210 in the trench T, as illustrated, for example, in FIG. 2B.

Further, the first plurality of contacts 230a may be formed in the protective film 290 and in the second, third, and fourth alignment films 260, 270, 280 and connected to the end portion of the first plurality of CNTs 210. The second plurality of contacts 230b may be formed in the protective film 290 and connected to the end portion of the second plurality of CNTs 220.

Further, as illustrated in FIG. 2B, the end portion of the second plurality of CNTs 220 is formed on the third alignment layer 270, and the second plurality of CNTs 220 extend from the second plurality of contacts 230b into the trench T toward the first alignment layer 250. As described in detail below, this structure may be obtained when the trench T is formed (e.g., by etching), causing the second plurality of CNTs 220 (e.g., a central portion of the plurality of CNTs 220) to fall down into the trench T.

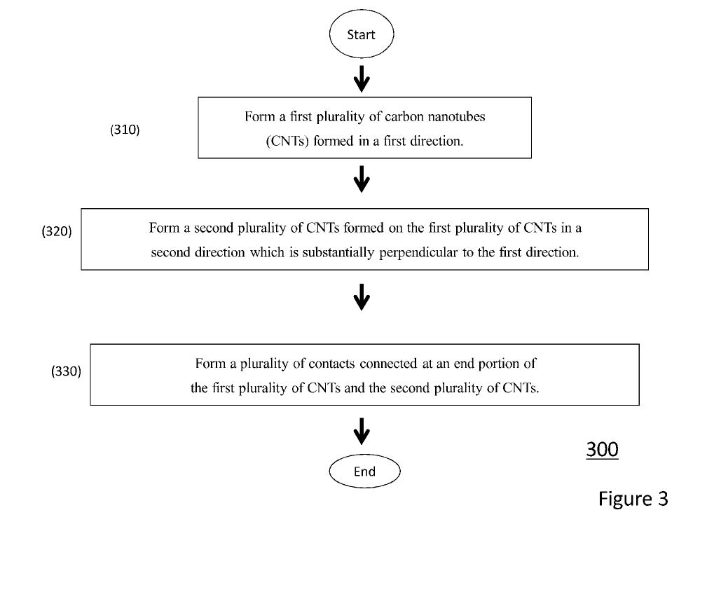

Referring again to the drawings, FIG. 3 illustrates a method 300 of forming a physical unclonable function (PUF), according to an exemplary aspect of the present invention. As illustrated in FIG. 3, the method 300 includes forming (310) a first plurality of carbon nanotubes (CNTs) formed in a first direction, forming (320) a second plurality of CNTs formed on the first plurality of CNTs in a second direction which is substantially perpendicular to the first direction, and forming (330) a plurality of contacts connected at an end portion of the first plurality of CNTs and the second plurality of CNTs.

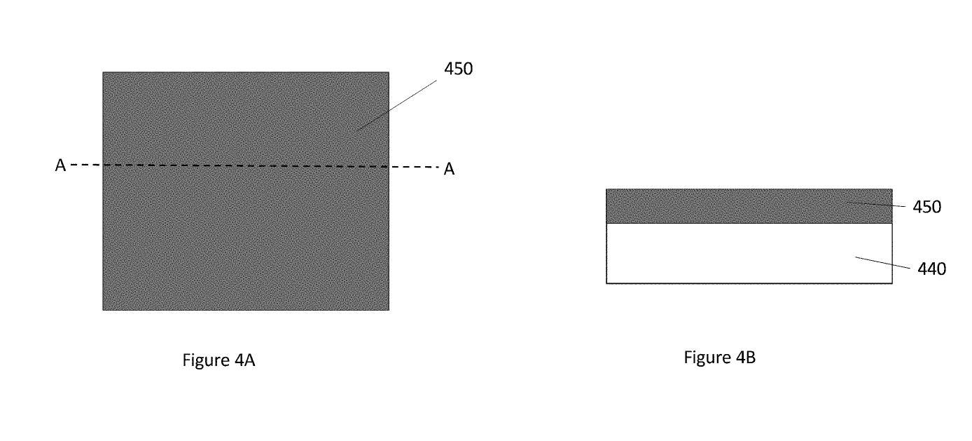

FIGS. 4A-12B illustrate a method 400 of forming a physical unclonable function (PUF), according to another exemplary aspect of the present invention.

In particular, FIG. 4A illustrates a topdown view (e.g., plan view) in the forming of a first alignment layer 450, according to an exemplary aspect of the present invention, and FIG. 4B illustrates a cross sectional view along line A-A in FIG. 4A in the forming of the first alignment layer 450, according to an exemplary aspect of the present invention.

As illustrated in FIGS. 4A-4B, a first alignment layer 450 is formed on a substrate 440. the substrate 440 may be, for example, a semiconductor or insulator substrate such as silicon, silicon oxide, germanium, sapphire, silicon carbide, etc. The first alignment layer 450 may include a material (e.g., hafnium oxide, silicon nitride) that will bond with carbon nanotubes after specific surface functionalization. The thickness of the first alignment layer 450 may be in a range from 1 nm to a few microns.

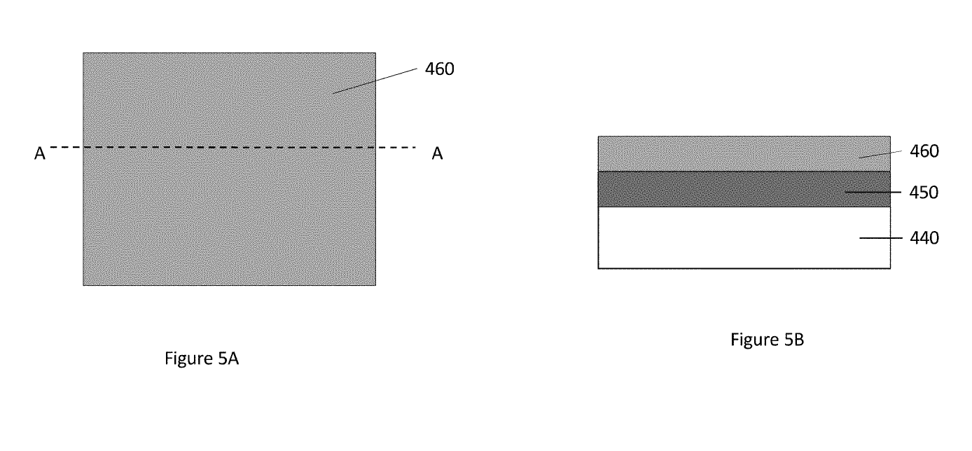

FIG. 5A illustrates a topdown view (e.g., plan view) in the forming of a second alignment layer 460, according to an exemplary aspect of the present invention, and FIG. 5B illustrates a cross sectional view along line A-A in FIG. 5A in the forming of the second alignment layer 460, according to an exemplary aspect of the present invention.

As illustrated in FIGS. 5A-5B, the second alignment layer 460 is formed on the first alignment layer 450. The second alignment layer 460 may include a material (e.g., silicon oxide) that is repulsive to functionalized nanotubes or has an affinity for carbon nanotubes which is less than the affinity for carbon nanotubes of the first alignment layer 450. The thickness of the second alignment layer 460 may also be in a range from 1 nm to 20 nm.

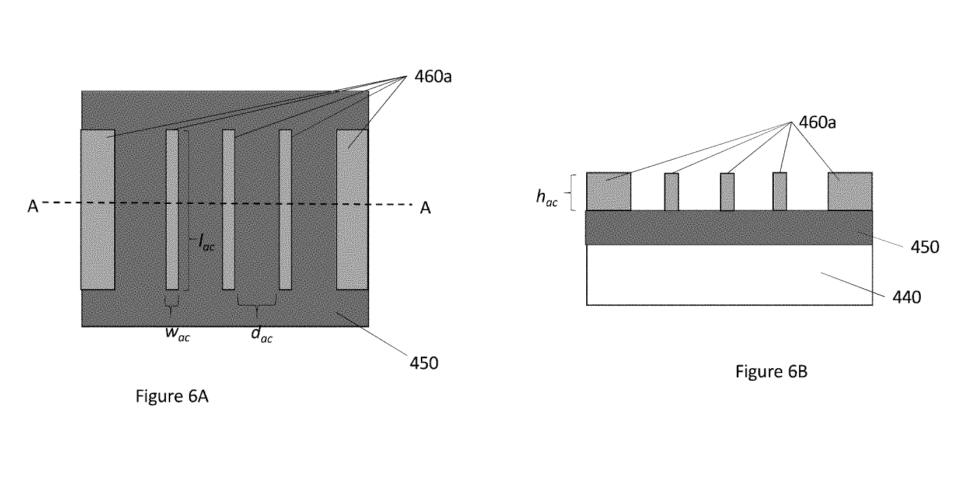

FIG. 6A illustrates a topdown view (e.g., plan view) in the forming of a plurality of alignment columns 460a, according to an exemplary aspect of the present invention, and FIG. 6B illustrates a cross sectional view along line A-A in FIG. 6A in the forming of the alignment columns 460a, according to an exemplary aspect of the present invention.

As illustrated in FIGS. 6A-6B, the second alignment layer is etched to form a plurality of alignment columns 460a which will be used later in this method to align CNTs on a surface of the first alignment layer 450. The plurality of alignment columns 460a should be aligned in the same direction as the CNTs to be formed on the first alignment film 450. Further, the width w_{ac} of an alignment column 460a may be in a range from 2 nm to 200 nm, the length l_{ac} of an alignment column 460a may be at least 80% of the length of the CNTs to be formed on the first alignment layer 450, the distance d_{ac} between the plurality of alignment columns 460a may be in a range from 2 nm to 200 nm, and the height h_{ac} of the plurality of alignment columns 460a may be substantially the same as the original (i.e., as deposited) thickness of the second alignment layer 460 (e.g., in a range from 1 nm to 20 nm).

The number of alignment columns 460a depends on the number of first CNTs 410 which are to be deposited (i.e., where the number of first CNTs 410 is N, the number of alignment columns 460a is N+1). The plurality alignment columns 460a should be arranged on the first alignment layer 450 so that a pair of alignment columns 460 are located equidistant from a desired location of a CNT to be formed on the first alignment layer 450.

After the alignment columns 460a are formed, a surface treatment may be performed on the surface of the first alignment layer 450 which is exposed between the alignment columns 460a, in order to make the surface of the first alignment layer 450 more attractive to the CNTs. For example, the surface of the first alignment layer 450 may be chemically functionalized by using a self-assembled monolayer, to make the surface of the first alignment layer 450 more attractive to the CNTs.

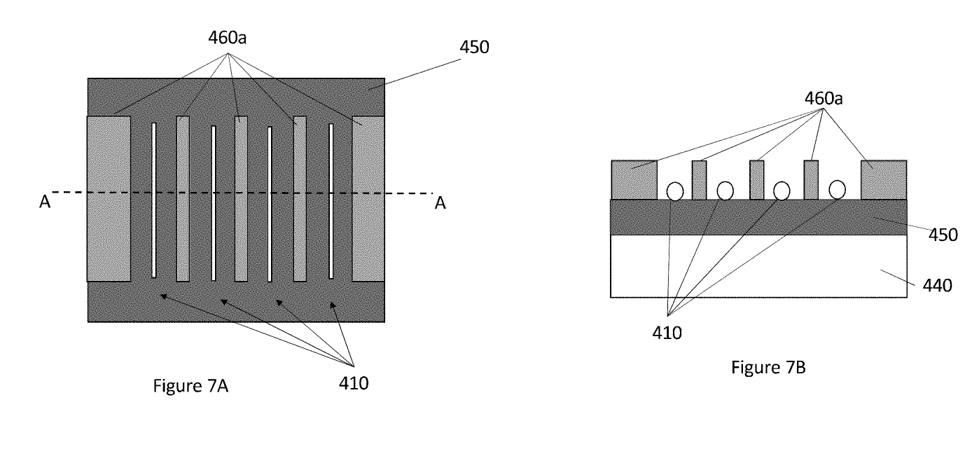

FIG. 7A illustrates a topdown view (e.g., plan view) in the depositing of a first plurality of CNTs 410, according to an exemplary aspect of the present invention, and FIG. 7B illustrates a cross sectional view along line A-A in FIG. 7A in depositing of a first plurality of CNTs 410, according to an exemplary aspect of the present invention.

As illustrated in FIGS. 7A-7B, the first plurality of CNTs 410 are deposited between the plurality of alignment columns 460a. That is, one (e.g., only one) CNT 410 is formed between a pair of alignment columns 460a.

The first plurality of CNTs 410 may be deposited, for example, by forming a slurry including the CNTs, depositing the slurry on the first and second alignment layers, and then heating in order to drive off the carrier in the slurry. Further, the first plurality of CNTs 410 should be substantially aligned so as to be substantially parallel to each other, and the end portions of the first plurality of CNTs 410 should be substantially aligned in a direction perpendicular to the lengthwise direction of the first plurality of CNTs 410.

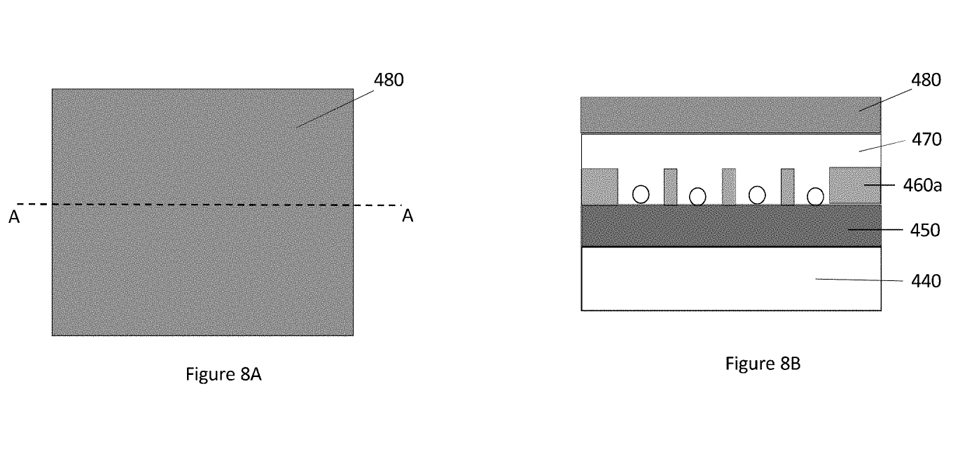

FIG. 8A illustrates a topdown view (e.g., plan view) in the forming of a third alignment film 470 and a fourth alignment film 480, according to an exemplary aspect of the present invention, and FIG. 8B illustrates a cross sectional view along line A-A in FIG. 8A in the forming of the third alignment film 470 and the fourth alignment film 480, according to an exemplary aspect of the present invention.

As illustrated in FIGS. 8A and 8B, the third alignment film 470 may be formed on the plurality of alignment columns 460a, and between the plurality of alignment columns 460a. In particular, the third alignment film 470 may be formed on the first CNTs 410 and on the first alignment film 450 between the plurality of alignment columns 460a.

The third alignment film 470 may include, for example, silicon nitride, and the fourth alignment film 480 may include, for example, silicon oxide.

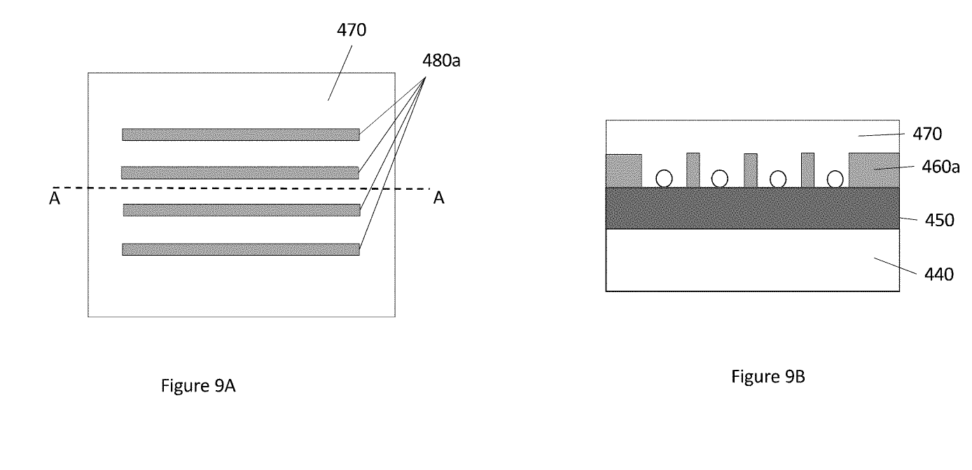

FIG. 9A illustrates a topdown view (e.g., plan view) in the forming of a plurality of alignment columns 480a, according to an exemplary aspect of the present invention, and FIG. 9B illustrates a cross sectional view along line A-A in FIG. 9A in the forming of the alignment columns 480a, according to an exemplary aspect of the present invention.

As illustrated in FIGS. 9A-9B, the fourth alignment film 480 may be etched to form a plurality of alignment columns 480a which will be used later in this method to align CNTs on a surface of the third alignment layer 470. The plurality of alignment columns 480a may be arranged and have dimensions and spacing which are similar to the plurality of alignment columns 460a described above.

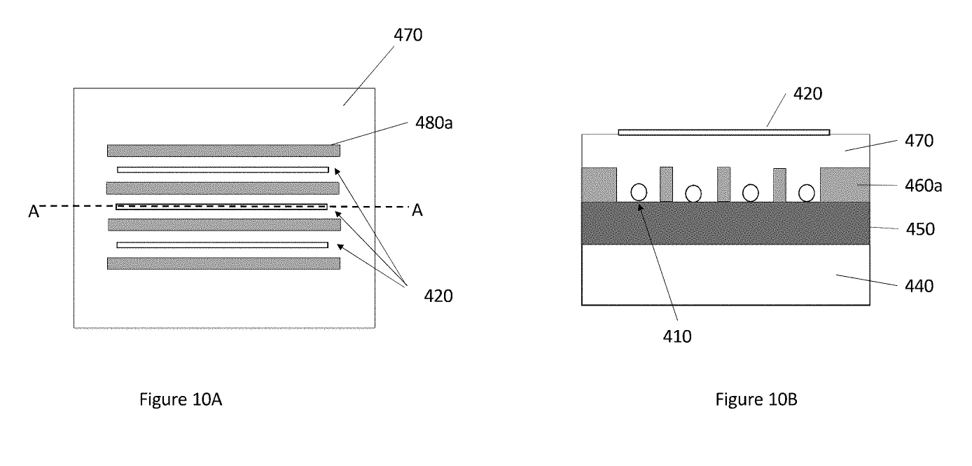

FIG. 10A illustrates a topdown view (e.g., plan view) in the depositing of the second plurality of CNTs 420, according to an exemplary aspect of the present invention, and FIG. 9B illustrates a cross sectional view along line A-A in FIG. 10A in the depositing of the second plurality of CNTs 420, according to an exemplary aspect of the present invention.

As illustrated in FIGS. 10A-10B, the second plurality of CNTs 420 may be deposited between the plurality of alignment columns 480a, in a manner similar to the manner in which the first plurality of CNTs 410 are deposited between the plurality of alignment columns 460a. Thus, for example, one (e.g., only one) CNT 420 may be formed between a pair of alignment columns 480a.

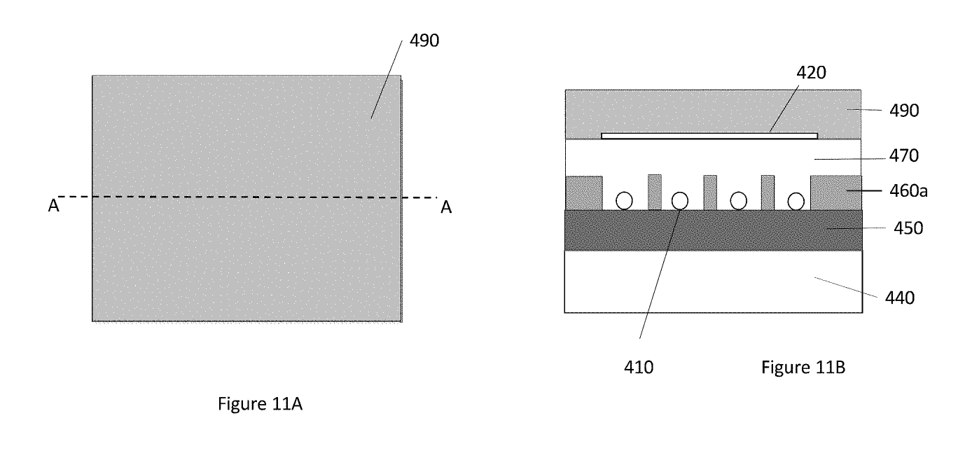

FIG. 11A illustrates a topdown view (e.g., plan view) in the forming of a protective film 490, according to an exemplary aspect of the present invention, and FIG. 11B illustrates a cross sectional view along line A-A in FIG. 11A in the forming of the protective film, according to an exemplary aspect of the present invention.

As illustrated in FIGS. 11A-11B, the protective film 490 may be formed on the plurality of alignment columns 480a, and between the plurality of alignment columns 480a. In particular, the protective film may be formed on the second CNTs 420 and on the third alignment layer 470 between the plurality of alignment columns 480a.

The protective film 490 may be used to protect the second CNTs 420 during subsequent processing, such as during a subsequent etching process. The protective film 490 may be formed, for example, of an oxide such as silicon oxide.

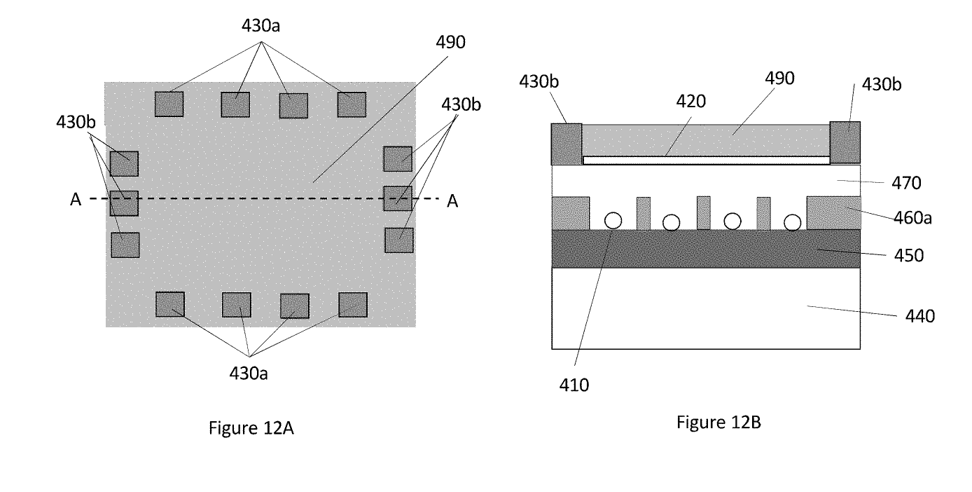

FIG. 12A illustrates a topdown view (e.g., plan view) in the forming of the contacts 430a, 430b, according to an exemplary aspect of the present invention, and FIG. 12B illustrates a cross sectional view along line A-A in FIG. 12A in the forming of the contacts 403a, 430b, according to an exemplary aspect of the present invention.

A plurality of via holes may be formed (e.g., by etching) in the protective film and the underlying alignment layers (e.g., the third alignment layer 470 and the second alignment layer 460), in order to expose an end portion of the contacts 430a, 430b. The plurality of via holes may then be formed with a conductive material such as polysilicon or a metal (e.g., gold) to form the plurality of contacts 430a, 430b. As a result, the plurality of contacts 430a contact the end portions of the first CNTs 410 and the plurality of contacts 430b contact the end portions of the second CNTs 420.

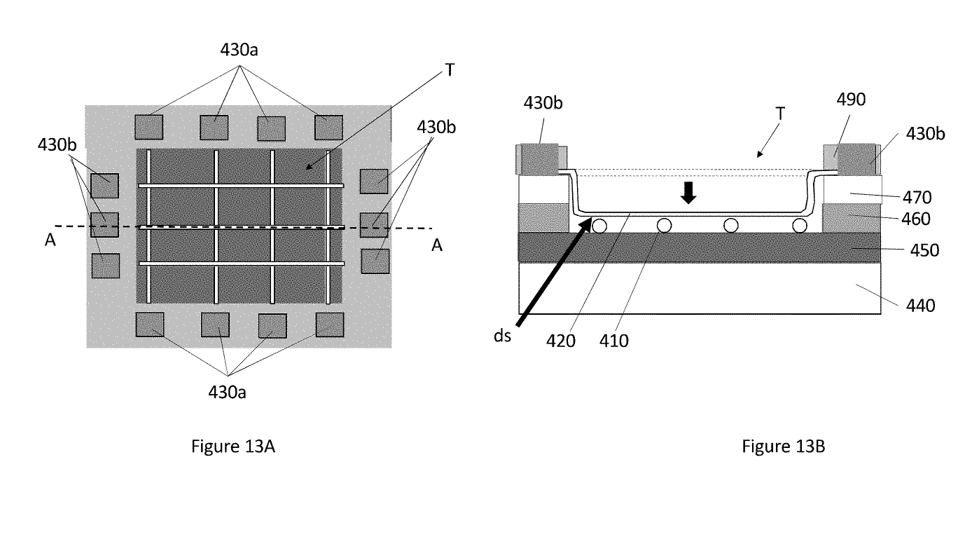

FIG. 13A illustrates a topdown view (e.g., plan view) in the formation of the trench T, according to an exemplary aspect of the present invention, and FIG. 13B illustrates a cross sectional view along line A-A in FIG. 13A in the forming of the trench T, according to an exemplary aspect of the present invention.

As illustrated in FIGS. 13A-13B, the trench T may be formed by etching (e.g., wet etching) the protective film and the second, third and fourth alignment layers, such that the second plurality of CNTs 420 falls in a direction toward the first alignment layer 450, and over the first plurality of CNTs 410.

It should be noted that since the alignment columns 460a, 480a are all that is left of the second and fourth alignment layers 460, 480, the forming of the trench T may include etching away of the alignment columns 460a, 480a. The resulting structure in FIGS. 13A-13B is substantially the same as the structure in FIGS. 2A-2B.

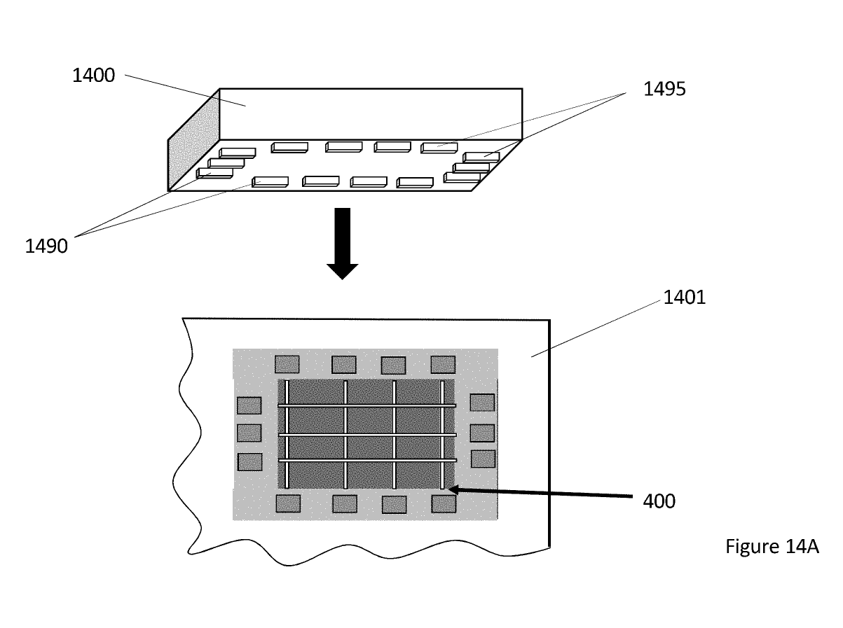

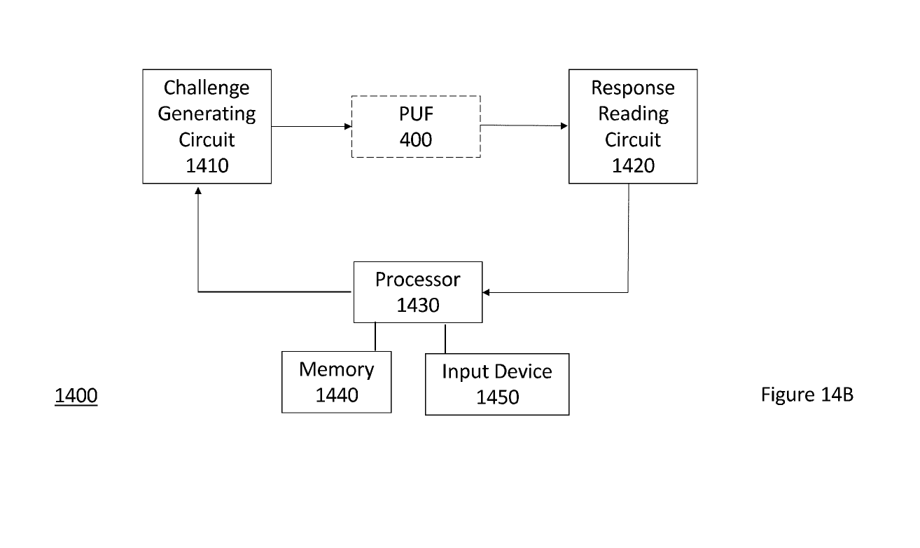

Referring again to the drawings, FIG. 14A illustrates a device 1400 for reading a physical unclonable function (PUF) which is affixed to an object such as the semiconductor chip 1401 and includes a plurality of crossed carbon nanotubes (CNTs), according to an exemplary aspect of the present invention.

As illustrated in FIG. 14A, the device 1400 may include a plurality of challenge contacts 1490 for inputting a challenge signal (e.g., challenge current) into the PUF 400, and a plurality of response contacts 1495 for reading a response of the PUF 400 to the challenge signal. For example, as illustrated in FIG. 14A, the challenge contacts 1490 may be arranged to correspond with a location of the contacts 430a on the PUF 400 at end portions of the first CNTs 410, and the response contacts 1495 may be arranged to correspond with a location of the contacts 430b on the PUF 400 at the end portions of the second CNTs 420.

Thus, to read the PUF 400, the device 1400 is placed down on the PUF 400 so that the challenge contacts 1490 and the response contacts 1495 contact the contacts 430a, 430b of the PUF 400, and the device 1400 inputs a challenge signal to the PUF 400 via the challenge contacts 1490, and reads the response via the response contacts 1495.

FIG. 14B illustrates the device 1400, according to another exemplary aspect of the present invention.

As illustrated in FIG. 14B, the device 1400 may include a challenge generating circuit 1410 (e.g., current source) which generates the challenge signal, and a response reading circuit (e.g., resistance detector) which detects a junction resistance for the plurality of crossed CNTs 410, 420 in the PUF 400.

The device 1400 may also include a processor 1430 (e.g., microprocessor) which causes the challenge generating circuit 1410 to generate the challenge signal, and processes the response (e.g., junction resistance) which is read from the response reading circuit 1420. The device 1400 may also include a memory device 1440 which may store a database which associates the detected junction resistance with the object (e.g., semiconductor chip 1401) on which the PUF 400 is affixed.

The device 1400 may also include an input device 1450 for inputting an instruction to the processor 1430 to cause the challenge to be generated. The input device 1450 may include, for example, a touchscreen display or a button which is depressed in order to input the instruction.

With its unique and novel features, the present invention provides a PUF which is significantly smaller than a conventional PUF and is inexpensive and easy to manufacture.

While the invention has been described in terms of one or more embodiments, those skilled in the art will recognize that the invention can be practiced with modification within the spirit and scope of the appended claims. Specifically, one of ordinary skill in the art will understand that the drawings herein are meant to be illustrative, and the design of the inventive method and system is not limited to that disclosed herein but may be modified within the spirit and scope of the present invention.

Further, Applicant's intent is to encompass the equivalents of all claim elements, and no amendment to any claim the present application should be construed as a disclaimer of any interest in or right to an equivalent of any element or feature of the amended claim.

What is claimed is:

1. A physical unclonable function (PUF) comprising:
a first plurality of carbon nanotubes (CNTs) formed in a first direction;
a second plurality of CNTs formed on the first plurality of CNTs in a second direction which is substantially perpendicular to the first direction; and
a plurality of contacts connected at an end portion of the first plurality of CNTs and the second plurality of CNTs.

2. The PUF of claim 1, wherein the first plurality of CNTs and the second plurality of CNTs comprise single-walled nanotubes (SWNT) including a diameter in a range of 0.6 nm to 3 nm, and a length in a range from 10 nm to 10 μm.

3. The PUF of claim 1, wherein a pitch between the first plurality of CNTs is in a range from 5 nm to 10 nm, and a pitch between the second plurality of CNTs is in a range from 5 nm to 200 nm.

4. The PUF of claim 1, wherein the first plurality of CNTs are substantially aligned in the first direction, and the second plurality of CNTs are substantially aligned in the second direction.

5. The PUF of claim 1, wherein the first plurality of CNTs are formed in a first horizontal plane and the second plurality of CNTs are formed in a second horizontal plane which is substantially parallel to the first plane.

6. The PUF of claim 1, wherein a distance between a CNT of the first plurality of CNTs is less than 4 nm.

7. The PUF of claim 1, further comprising:
a first alignment layer formed on a substrate, the first plurality of CNTs being formed on the first alignment layer.

8. The PUF of claim 7, further comprising:
a second alignment layer formed on the first alignment layer;
a third alignment layer formed on the second alignment layer;
a fourth alignment layer formed on the third alignment layer;
a protective film formed on the fourth alignment layer,
wherein a trench is formed in the protective film and in the second, third and fourth alignment films, a surface of the first alignment film forming a bottom of the trench, and
wherein the second plurality of CNTs cross over the first plurality of CNTs in the trench.

9. The PUF of claim 8, wherein the plurality of contacts comprises:
a first plurality of contacts which are formed in the protective film and in the second, third, and fourth alignment films, and are connected to the end portion of the first plurality of CNTs; and
a second plurality of contacts which are formed in the protective film and are connected to the end portion of the second plurality of CNTs.

10. The PUF of claim 9, wherein the end portion of the second plurality of CNTs is formed on the third alignment layer, and the second plurality of CNTs extend from the second plurality of contacts into the trench toward the first alignment layer.

11. A method of forming a physical unclonable function (PUF), the method comprising:
forming a first plurality of carbon nanotubes (CNTs) formed in a first direction;
forming a second plurality of CNTs formed on the first plurality of CNTs in a second direction which is substantially perpendicular to the first direction; and
forming a plurality of contacts connected at an end portion of the first plurality of CNTs and the second plurality of CNTs.

12. The method of claim 11, wherein the forming of the first plurality of CNTs comprises:
forming a first alignment layer on a substrate;
forming a second alignment layer on the first alignment layer;
etching the second alignment layer to form a first plurality of alignment columns in the first alignment layer; and
depositing a first plurality of carbon nanotubes (CNTs) between the first plurality of alignment columns.

13. The method of claim 12, wherein the forming of the second plurality of CNTs comprises:
forming a third alignment layer on the second alignment layer;
forming a fourth alignment layer on the third alignment layer;
etching the fourth alignment layer to form a second plurality of alignment columns on the third alignment layer; and
depositing a second plurality of CNTs between the second plurality of alignment columns.

14. The method of claim 13, wherein the forming of the contacts comprises:
forming a protective film on the fourth alignment layer and the second plurality of CNTs;
forming a plurality of via holes in the protective film; and
filling the plurality of via holes with conductive material to form the plurality of contacts.

15. The method of claim 14, further comprising:
etching the protective film and the second, third and fourth alignment layers, such that the second plurality of CNTs falls in a direction toward the first alignment layer, and over the first plurality of CNTs.

16. The method of claim 11, wherein the first and second plurality of CNTs comprise single-walled nanotubes (SWNT) including a diameter in a range of 0.6 nm to 3 nm, and a length in a range from 10 nm to 10 μm.

17. The method of claim 11, wherein a pitch between the first plurality of CNTs is in a range from 5 nm to 200 nm, and a pitch between the second plurality of CNTs is in a range from 5 nm to 200 nm.

18. The method of claim 11, wherein the first plurality of CNTs are substantially aligned in the first direction, and the second plurality of CNTs are substantially aligned in the second direction.

19. A semiconductor chip comprising the PUF of claim 1.

20. A device for reading a physical unclonable function (PUF) which is affixed to an object and includes a plurality of crossed carbon nanotubes (CNTs), comprising:
a current source for applying a current to a the plurality of crossed CNTs; and
a resistance detector for detecting a junction resistance for the plurality of crossed CNTs.
